(19) United States
(12) Patent Application Publication
(10) Pub. No.: US 2020/0181407 A1
(43) Pub. Date: Jun. 11, 2020

(54) ELECTRONICS PACKAGING USING ORGANIC ELECTRICALLY INSULATING LAYERS

(71) Applicant: Alliance for Sustainable Energy, LLC, Golden, CO (US)

(72) Inventors: Douglas John DeVOTO, Boulder, CO (US); Joshua John MAJOR, Kittredge, CO (US); Kevin Scott BENNION, Littleton, CO (US); Sreekant Venkat Jagannath NARUMANCHI, Littleton, CO (US); Paul Philip PARET, Thornton, CO (US); Gilberto MORENO, Thornton, CO (US); Justine Emily COUSINEAU, Lakewood, CO (US)

(21) Appl. No.: 16/707,179

(22) Filed: Dec. 9, 2019

Related U.S. Application Data
(60) Provisional application No. 62/776,506, filed on Dec. 7, 2018.

(51) Int. Cl. C08L 79/08; H01L 23/00; H01L 23/373; H01L 25/065

(52) U.S. Cl. CPC C08L 79/08; H01L 24/29; H01L 2224/73251; H01L 25/0657; H01L 2224/32238; H01L 23/3737

(57) ABSTRACT

Disclosed herein are power electronics modules that include a polyimide film. For example, the power electronics modules described herein utilize polyimide film as a substrate and are capable of three-dimensional (3D) heat removal of semiconductors.

### CROSS-REFERENCE TO RELATED APPLICATIONS

This application claims the benefit of U.S. Provisional Application No. 62/776,506 filed on Dec. 7, 2018, the contents of which are incorporated herein by reference in their entirety.

### CONTRACTUAL ORIGIN

The United States Government has rights in this invention under Contract No. DE-AC36-08G028308 between the United States Department of Energy and Alliance for Sustainable Energy, LLC, the Manager and Operator of the National Renewable Energy Laboratory.

### BACKGROUND

In electric vehicles and other applications, the power electronics package is responsible for controlling and converting electrical power. FIG. 1 illustrates a typical prior art power electronics package stackup 100. The stackup 100 includes a integrated baseplate/heat exchanger 105, a metalized substrate 110, substrate attach 115, semiconductor (or heat source) device 120, interconnect 125, die attach, 130, encapsulant 135, enclosure 140, and terminal 145. During operation, a significant amount of heat is generated by the semiconductor device 120 that needs to be removed to keep temperatures within limits. However, due to the roughness of the component surfaces in contact with each other, air gaps are formed between the surfaces and can cause a large resistance to heat transfer, which in turn results in large increases in temperatures in the package. Bonded materials attempt to create an efficient path for heat transfer at the interfaces by closing these air gaps. Hence, the semiconductor device 120 is typically attached by a bonded material such as solder at the die-attach level to the metallized substrate 110. The metallized substrate 110 is typically composed of a ceramic bounded by copper layers on either side and provides electrical insulation. The copper layers on either side may help to prevent fracturing.

The metallized substrate 110 is mounted onto the baseplate 105 via the substrate attach 115. The integrated baseplate/heat exchanger is typically made of copper or aluminum. The substrate attach 115 is typically another solder alloy or a grease.

The solder layer is common failure location within a power electronics package as cracks and voids can propagate over time, causing an increase in package thermal resistance and device junction temperature.

Electrically insulating substrates typically used in power electronics modules utilize a ceramic layer, comprised most commonly of either aluminum oxide (Al₂O₃), aluminum nitride (AlN), or silicon nitride (Si₃N₄). Thin copper (Cu) layers may be bonded to either side of the substrate using a direct-bond-Copper (DBC) or active metal brazing (AMB) process.

The foregoing examples of the related art and limitations therewith are intended to be illustrative and not exclusive. Other limitations of the related art will become apparent to those of skill in the art upon a reading of the specification and a study of the drawings.

### SUMMARY

An aspect of the present disclosure is a device including a first baseplate, a semiconductor, a first layer of polyimide substrate bonded to the first baseplate, and a first voltage terminal, wherein the semiconductor is configured to be in electrical communication with the first voltage terminal, and the semiconductor is configured to be in thermal communication with the first layer of polyimide substrate. In some embodiments, the device also includes a die attach, wherein the die attach is in thermal communication with the semiconductor device and the polyimide substrate, and the die attach is positioned between the semiconductor device and the polyimide substrate. In some embodiments, the device also includes a second voltage terminal, a second baseplate, and a second layer of polyimide substrate, wherein the semiconductor is configured to be in thermal communication with the second voltage terminal, the semiconductor device is configured to be in thermal communication with the second layer of polyimide substrate, and the second layer of polyimide substrate is bonded to the second baseplate. In some embodiments, the first voltage terminal is a direct current (DC) terminal. In some embodiments, the first voltage terminal is an alternating current (AC) terminal. In some embodiments, the first voltage terminal is a gate terminal. In some embodiments, the second voltage terminal is a DC terminal. In some embodiments, the second voltage terminal is an AC terminal. In some embodiments, the second voltage terminal is a gate terminal.

An aspect of the present disclosure is a device including a first plate being substantially planar, a second plate being substantially planar and configured to be substantially parallel to the first plate, a first layer of polyimide substrate bonded to the first plate, a second layer of polyimide substrate bonded to the second plate, a first semiconductor thermally connected to the first layer of polyimide substrate, and a second semiconductor thermally connected to the second layer of polyimide substrate, wherein the first semiconductor and the second semiconductor are in electrical communication by a first voltage terminal. In some embodiments, the first voltage terminal is an alternating current (CD) terminal. In some embodiments, the device also includes a first die attach connected to a first side of the first semiconductor, a second die attach connected to a second side of the first semiconductor, a third die attach connected to a third side of the second semiconductor, a fourth die attach connected to a fourth side of the second semiconductor, and a second voltage terminal, wherein the second voltage terminal is in thermal communication with the polyimide substrate, and the second voltage terminal is a direct current (DC) terminal.

An aspect of the present disclosure is a system including a first plurality of semiconductor devices, each substantially planar, a first voltage terminal having a substantially planar shape in a first plane, with a plurality of planar protrusions extending radially outward from a point in the first plane, each configured to be electrically connected to a surface of a respective semiconductor device, a second voltage terminal having a substantially planar shape in a second plane, with a plurality of planar protrusions extending radially outward from a point in the first plane, each configured to be electrically connected to a surface of a respective semiconductor device, a first polyimide substrate having a substantially planar shape, being in thermal communication with the plurality of semiconductor devices, the first voltage terminal, and the second voltage terminal, and a first baseplate in physical contact with the polyimide substrate. In some embodiments, the first voltage terminal is a gate terminal, and the second voltage terminal is a direct current (DC) terminal. In some embodiments, the system also includes a first plurality of die attaches, each configured to be in thermal communication with a respective semiconductor device and the second voltage terminal, and a second plurality of die attaches, each configured to be in thermal communication with a respective semiconductor device and the first voltage terminal. In some embodiments, the first plurality of die attaches and the second plurality of die attaches are substantially planar and comprise a metal. In some embodiments, the system also includes a second plurality of semiconductor devices, each substantially planar, a third voltage terminal having a substantially planar shape in a first plane, with a plurality of planar protrusions extending radially outward from a point in the first plane, each configured to be electrically connected to a surface of a respective semiconductor device, a fourth voltage terminal having a substantially planar shape in a second plane, with a plurality of planar protrusions extending radially outward from a point in the first plane, each configured to be electrically connected to a surface of a respective semiconductor device, a second polyimide substrate having a substantially planar shape, being in thermal communication with the plurality of semiconductor devices, the first voltage terminal, and the second voltage terminal, and a second baseplate in physical contact with the polyimide substrate. In some embodiments, the third voltage terminal is a gate terminal, and the fourth voltage terminal is a direct current (DC) terminal. In some embodiments, the system also includes a third plurality of die attaches, each configured to be in thermal communication with a respective semiconductor device and the fourth voltage terminal, and a fourth plurality of die attaches, each configured to be in thermal communication with a respective semiconductor device and the third voltage terminal. In some embodiments, the third plurality of die attaches and the fourth plurality of die attaches are substantially planar and comprise a metal.

### BRIEF DESCRIPTION OF THE DRAWINGS

Exemplary embodiments are illustrated in referenced figures of the drawings. It is intended that the embodiments and figures disclosed herein are considered to be illustrative rather than limiting.

FIG. 1 illustrates a prior art electronics package stackup.

FIG. 2 illustrates an electronics package, as described in some embodiments herein.

FIG. 3 illustrates an electronics package with a polyimide film directly bonded to the baseplate/heat exchanger as described in some embodiments herein.

FIG. 4 illustrates a double-sided cooling package with polyimide substrate as described in some embodiments herein.

FIG. 5 illustrates a double-sided cooling package with stacked devices in a three-dimensional (3D) design as described by some embodiments herein.

FIGS. 6 A-C show multiple views of a 3D power electronics package 600.

FIG. 7 illustrates an expanded view of some of the layers within a 3D power electronics module as described in some embodiments herein.

FIG. 8 shows the thermal resistance (mm² K/W) versus dielectric strength (kV) for insulating substrates, including polyimide substrates as described in some embodiments herein.

FIG. 9 shows the thermal resistance (K/W) for transient thermal measurements of substrates, include polyimide substrates as described in some embodiments herein.

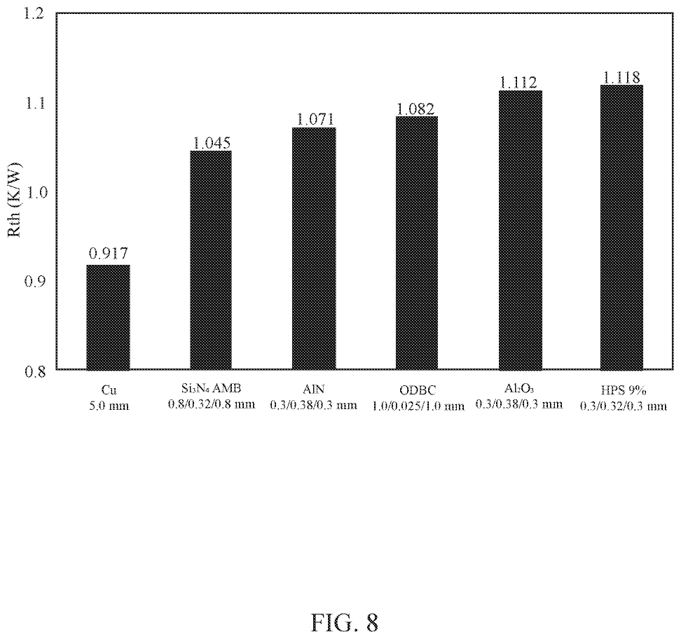

### DETAILED DESCRIPTION OF SOME EMBODIMENTS

Disclosed herein are power electronics modules that include a polyimide film. For example, power electronics modules may utilize polyimide film as a substrate in accordance with the techniques described herein, thereby improving device heat dissipation and performance. Polyimide films in power electronics modules may allow for direct bonding to a heat changer or cold plate and eliminate the need for an intermediate bonding layer (such as a solder layer). Polyimide film is robust and flexible and may enable higher operating temperatures, reduced thermochemical stresses, and may allow for higher bonding pressures and temperatures during the manufacture of the package. The polyimide film may be used as a replacement in traditional power electronics stackups, may be used in double-sided cooling of devices, or may enable cooling of encapsulated component areas within a 3D structure, defined as stacking semiconductor devices vertically.

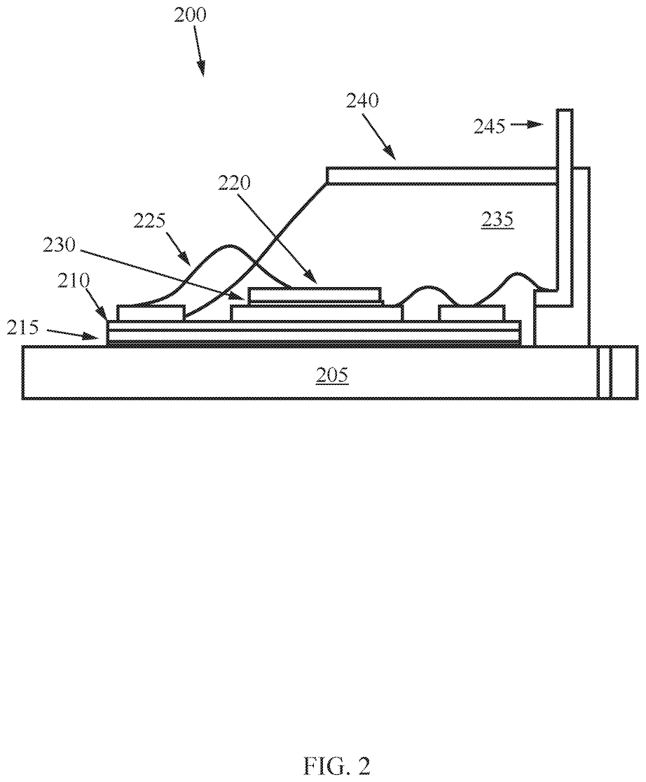

FIG. 2 illustrates an electronics package with a polyimide film in place of a ceramic substrate as described by some embodiments herein. The package 200 includes an integrated baseplate/heat exchanger 205, a polyimide substrate 210, a substrate attach 215, a semiconductor device 220, interconnect 225, die attach 230, encapsulant 235, enclosure 240, and a terminal 245. The integrated baseplate/heat exchanger 205 serves as a heat spreader or heat sink for heat generated by the semiconductor device 220. The heat dissipated by the semiconductor device 220 flows first through the die attach 230. The die attach may be a a metal or metal compound, such as gold-silicon (AuSi) or gold-tin (AuSn). The encapsulant 235 provides protection to the package 200 against adverse environmental conditions, such as moisture, contaminants, mobile ions, radiations, and other mechanical damage. The encapsulant 235 may also prevent corrosion in the package 200. The enclosure 240 provides waterproof protection to the semiconductor device 220 and the entire package 200. The terminal 245 serves as a location where additional circuits (such as additional packages) may be connected via electrical communication. The interconnect 225 serves to connect multiple semiconductor devices. The polyimide film 210 may be connected to the integrated baseplate/heat exchanger 205 by the substrate attach 215. The substrate attach 215 may also be referred to as the solder layer.

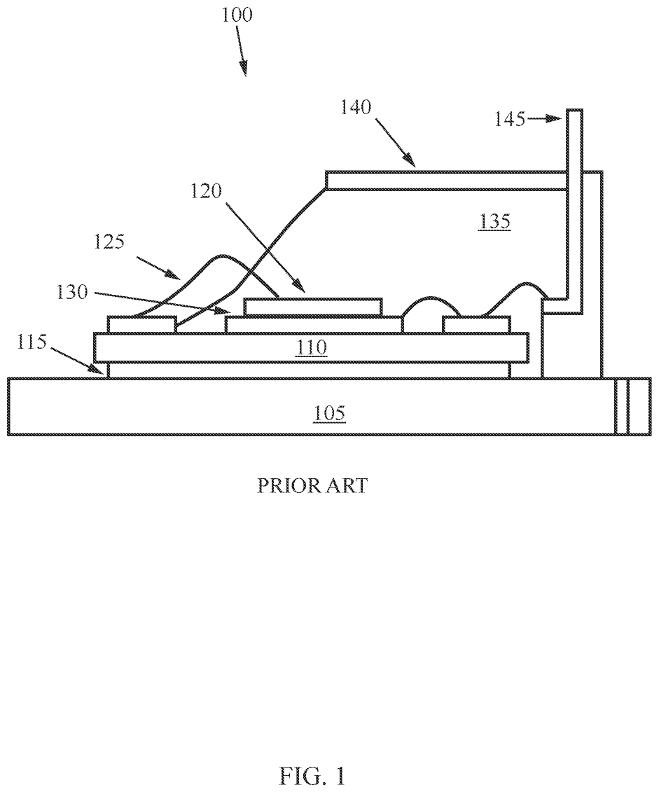

Replacing brittle substrates with polyimide film may have several benefits. Thermal cycling experiments have shown that polyimide substrates better withstand the coefficient of thermal expansion mismatches within a package and can survive temperature extremes of −40° C. and 200° C. for up to 5,000 cycles. Additional thermal aging, power cycling, and electrical high potential testing have further validated the performance of this substrate. This may far exceed the mechanical capabilities of traditional substrates while still maintaining the necessary electrical isolation. Note that the distinction between FIG. 2 and FIG. 1 is the polyimide substrate 210, which is used in place of the metallized substrate 110 in FIG. 1.

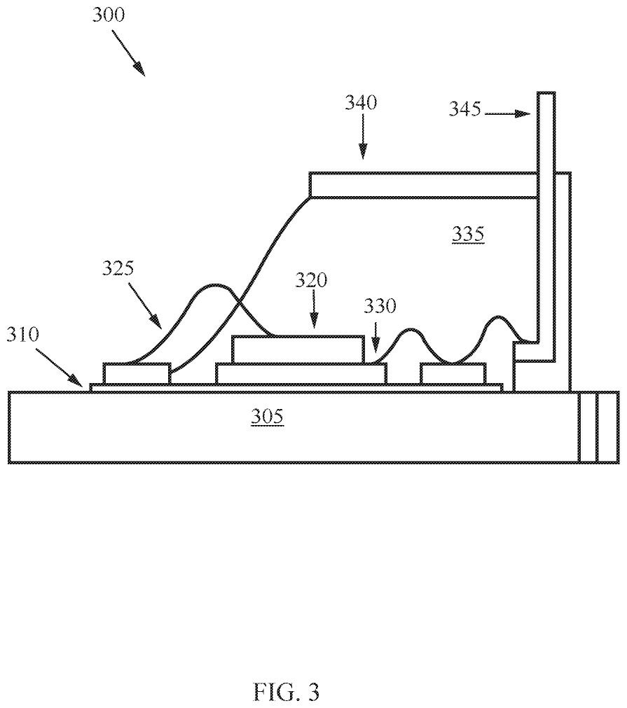

The bonding process of polyimide film does not require matching top and bottom metallization layers. Each metallization layer may be optimized independently, and different thicknesses and materials may be selected. The polyimide may be directly bonded to a cold plate or heat spreader, eliminating the requirement for the bottom metallization layer and the substrate-attached solder layer. this may reduce the thermal resistance pathway between the device and coolant, eliminate the common failure mechanism of solder fatigue, allow for higher-temperature operation above the reflow temperature of solder, and reduce manufacturing time and material costs. An embodiment of this direct bonding design is demonstrated in FIG. 3.

FIG. 3 illustrates an electronics package with a polyimide film directly bonded to the baseplate/heat exchanger as described in some embodiments herein. The electronics package 300, includes an integrated baseplate/heat exchanger 305, a polyimide substrate 310 bonded to the base plate 305, a semiconductor device 320, an interconnect 325, a die attach 330, an encapsulant 335, an enclosure 340, and a terminal 345. This embodiment shows how a polyimide film 310 may be used in an electronics package 300 by being directly bonded to the baseplate 305. By removing the bottom metallization layer and solder layer (shown as the substrate attach 215 in FIG. 2), the thermal pathway from the semiconductor device 320 to the integrated baseplate/heat exchanger 305 is improved. Additionally, elimination of the solder layer improves the reliability of the electronic package 300 compared to traditional electronics packages, such as 100 in FIG. 1.

In FIG. 3, the integrated baseplate/heat exchanger 305 is analogous to the integrated baseplate/heat exchanger 205 of FIG. 2. The semiconductor device 320 is analogous to the semiconductor device 220 of FIG. 2. The die attach 330 is analogous to the die attach 230 of FIG. 2. The enclosure 340 and encapsulant 335 is analogous to the enclosure 240 and encapsulant 235 of FIG. 2. The terminal 345 is analogous to the terminal 245 of FIG. 2. In FIG. 2, the polyimide substrate 310 is bonded directly to the integrated baseplate/heat exchanger 305.

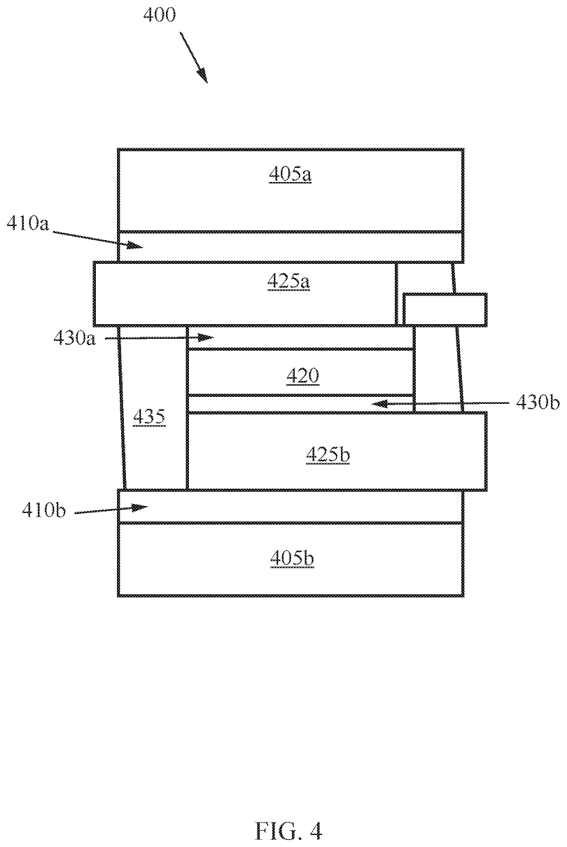

Polyimide film may also be used in a double-sided cooling package because it does not require an outer metallization layer and substrate attached layer. FIG. 4 illustrates a double-sided cooling package with polyimide substrate as described by some embodiments herein. The double-sided cooling package 400, includes two baseplates 405a and 405b, two polyimide substrate layers 410a and 410b, two interconnect/terminal layers 425a and 425b, two die attach layers 430a and 430b, an encapsulant 435, and a semiconductor device 420. The baseplates 405a and 405b serve to contain and protect the other elements of the double-sided cooling package 400. The interconnect/terminal layers 425a and 425b allow for the double-sided cooling package 400 to be connected to other cooling packages and/or other semiconductor devices. The encapsulant 435 further protects the semiconductor device 420. The die attach 430a and 430b serves as a heat transfer medium between the semiconductor device 420 and the polyimide substrate 410a and 410b. The polyimide substrate layers 410a and 410b may be bonded directly to the baseplates 405a and 405b and the interconnect 425a and 425b.

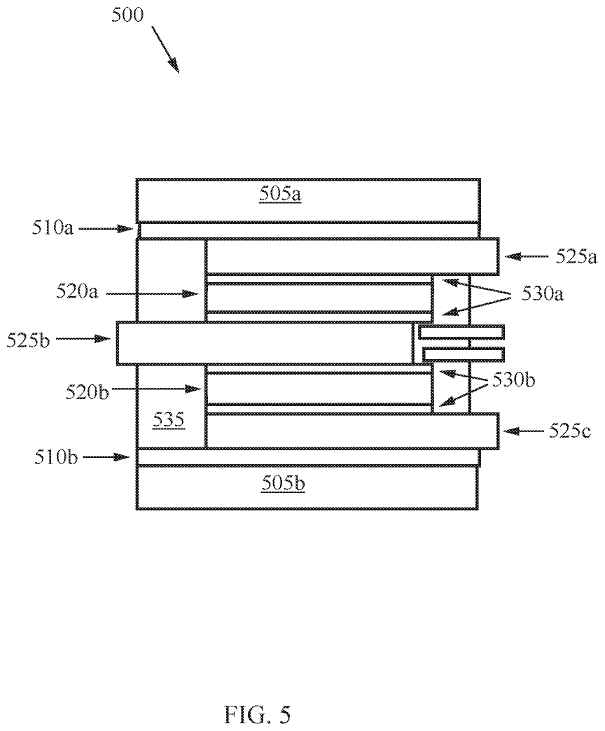

A polyimide-based design can be incorporated into new circuit board structures to transport heat out of encapsulated component areas within a three-dimensional (3D) structure, as defined as stacking semiconductor devices vertically. FIG. 5 illustrates a double-sided cooling package with stacked devices in a 3D design as described by some embodiments herein. The 3D cooling package 500, includes two baseplates 505a and 505b, two polyimide substrates 510a and 510b, two semiconductor devices 520a and 520b, three interconnect/terminals 525a, 525b, and 525c, two die attach 530a and 530b, and an encapsulant 535. The die attach 530a and 530b are on either side of the semiconductor devices 520a and 520b serving as heat transfer media. The die attach 530a and 530b allow for heat to the interconnect/terminal layers 525a, 525b, and 525c. The encapsulant 535 provides protection to the semiconductor devices 520a and 520b and the other components of the 3D cooling package 500. The 3D package 500 allows for more efficient cooling of semiconductor devices 520a and 520b, as more surfaces are used for conductive cooling.

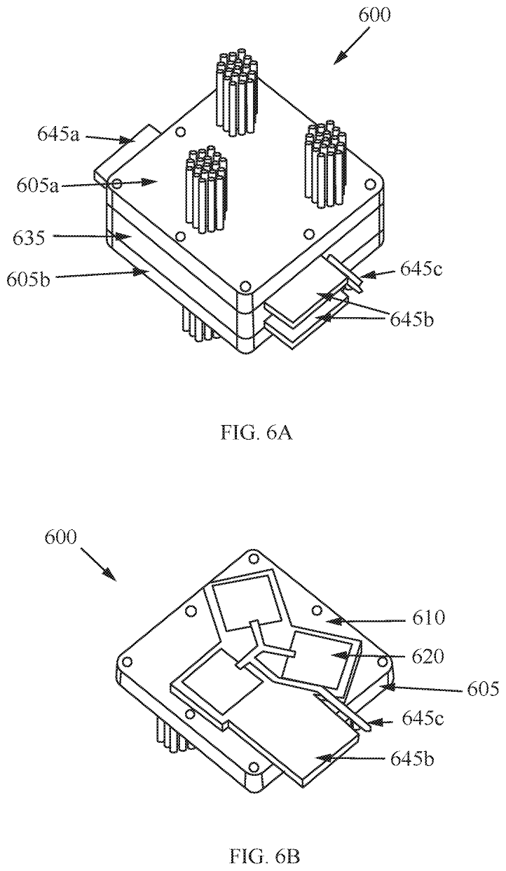

FIGS. 6 A-C show multiple views of a 3D power electronics package 600. FIG. 6A shows an external view of the 3D power electronics package 600. The 3D power electronics package contains two baseplates 605a and 605b, an encapsulant 635, and multiple terminals 645a, 645b, and 645c. The baseplates 605a and 605b act as heat spreaders or heat sinks for the 3D power electronics package 600. The baseplates 605a and 605b may be a metal, metal-containing compound, or another solid material. The encapsulant 635 provides protection to the semiconductor devices (not shown in FIG. 6A, but shown in FIGS. 6B-C) and other internal components of the 3D power electronics package 600. The terminals 645a, 645b, and 645c are an alternating current (AC) terminal 645a, a direct current (DC) terminal 645b, and a gate terminal 645c. The terminals 645a, 645b, and 645c allow the 3D power electronics package 600 to be connected to other packages, devices, or systems, by electrical means.

FIG. 6B shows the lower half view of the 3D power electronics package 600. This view shows how the 3D power electronics package package 600 includes an integrated baseplate/heat exchanger 605a, a polyimide substrate 610, three semiconductor devices 620, a DC terminal 645b, and a gate terminal 645c. The semiconductor devices 620 may be connected to other semiconductors or electronics devices by the DC terminal 645b and the gate terminal 645c. The six devices 620 are configured to operate as half bridge module (note only 3 devices 620 are shown in FIG. 6B, the others are shown in FIG. 6C). Sintered silver may be used bond the semiconductor devices 620 to the electrical interconnects/busbars while polyimide film 610 electrically isolates the internal components from the integrated baseplate/heat exchanger 605. Both sintered silver and polyimide require an elevated temperature and pressure to complete their synthesis. This means that after the initial assembly, all layers can be bonded simultaneously in one sintering/bonding steps. The reduction in manufacturing time is an additional benefit to using polyimide substrates in place of traditional ceramic substrates.

An exploded view of the 3D power electronics package 600 is shown in FIG. 6C. This view shows how the 3D power electronics package 600 includes an encapsulant 635, a gate terminal 645c, a die attach 630a, semiconductor devices 620, more die attach 630b, a DC terminal 645b, a layer of polyimide substrate 610, an integrated baseplate/heat exchanger 605, and a cold plate enclosure 650. As the partial exploded 3D module only shows approximately half of the device, the layers shown would be repeated above the alternating current terminal 645a and encapsulant 635, mirrored from what is shown in FIG. 6C. That is, another layer of devices 620 would be positioned above the layers shown, allowing for the semiconductor devices to be stacked vertically. The encapsulant 635 serves to contain and protect the other elements of the 3D power electronics package 600. The encapsulant may be a polymer or a plastic material. The gate terminal 645c and DC terminal 645b may be used to connect the semiconductor devices 620 to other semiconductor devices, other electronics devices, or an electric current. The different voltage terminals may be substantially planar. The shape and size of the respective voltage terminal depends on its function and the semiconductor or other electronics devices it is connecting. The die attach 630a and 630b serves as a heat transfer medium from the semiconductor device 620 to the polyimide substrate 610. The die attach may be a metal or metal-containing compound. The integrated baseplate/heat exchanger 605 serves as a heat sink or heat spreader for heat removed from the semiconductor devices 620. In some embodiments the heat removed from the semiconductor device 620 may be transferred out of the 3D power electronics package 600 by a shell and tube heat exchanger (not shown). The heat removed from the semiconductor device 620 may be further dissipated in the cold plate enclosure 650.

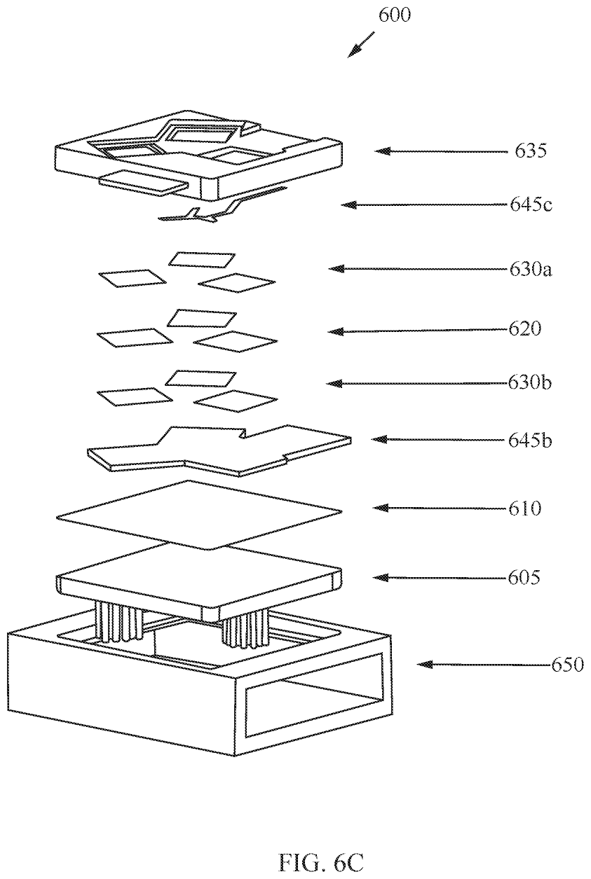

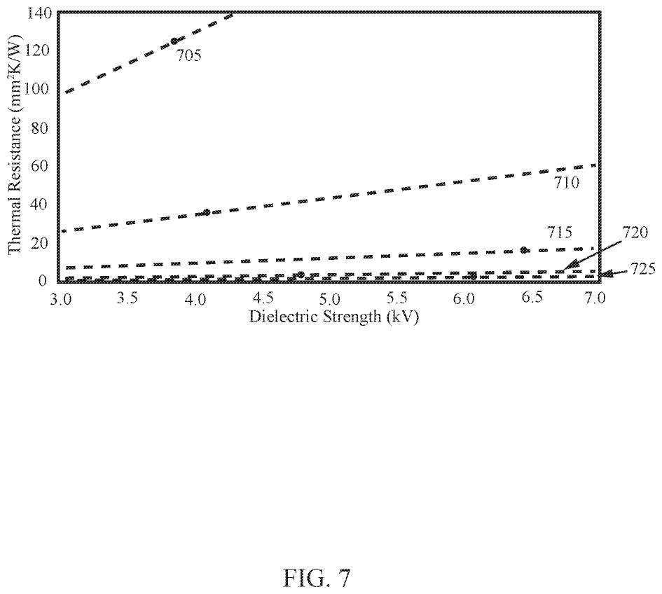

FIG. 7 shows the thermal resistance (mm² K/W) versus dielectric strength (kV) for insulating substrates, including polyimide substrates as described in some embodiments herein. FIG. 8 shows the thermal resistance (K/W) for transient thermal measurements of substrates, include polyimide substrates as described in some embodiments herein. Characterization of polyimide-based substrates has shown they have similar dielectric strength, as shown in FIG. 7. Line 705 shows Kapton® (a polyimide film developed by DuPont), line 710 shows Temprion™, line 715 shows aluminum oxide (Al₂O₃), line 720 shows silicon nitride (Si₃N₄), and line 725 shows aluminum nitride (AlN). FIG. 7 and FIG. 8 show that while the polyimide Temprion has a significantly lower thermal conductivity than Si₃N₄, only 25 μm of the polyimide is needed to achieve a dielectric strength of 4 kV, compared to 275 μm needed for Si₃N₄. The reduced thickness requirement for the polyimide allows for a thermal resistance of approximately 35 mm²K/W. When bonded to copper metallization layers, experimental transient thermal experiments measured a similar thermal resistance for the organic direct bonded copper (ODBC) substrate as traditional substrates. The ODBC benefits from the thicker topside copper metallization layer, which allows heat to spread laterally through a package from a device more quickly than traditional substrates. The thermal resistance of the organic substrate can be further reduced by implementing the designs previously outlined by removing the bottom metallization and attach layers. HPS shows high performance substrate (specifically zirconia toughened alumina) a ceramic substrate.

Thermal cycling performed have shown that polyimide substrates better withstand the coefficient of thermal expansion mismatches within a package and can survive temperature extremes of 40° C. and 200° C. for 5000 cycles. Additional thermal aging, power cycling, and electrical high-potential evaluation have further validated the performance of this substrate. This far exceeds the mechanical capabilities of traditional ceramic substrates while still maintaining the necessary electrical isolation.

The foregoing discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations may be combined in alternate aspects, embodiments, or configurations other than those discussed above. This method of disclosure is not to be interpreted as reflecting an invention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration. What is claimed is:

1. A device comprising:
a first baseplate;
a semiconductor;
a first layer of polyimide substrate bonded to the first baseplate; and
a first voltage terminal; wherein:
the semiconductor is configured to be in electrical communication with the first voltage terminal, and
the semiconductor is configured to be in thermal communication with the first layer of polyimide substrate.

2. The device of claim 1, further comprising a die attach, wherein:
the die attach is in thermal communication with the semiconductor device and the polyimide substrate, and
the die attach is positioned between the semiconductor device and the polyimide substrate.

3. The device of claim 1, further comprising:
a second voltage terminal;
a second baseplate; and
a second layer of polyimide substrate; wherein:
the semiconductor is configured to be in thermal communication with the second voltage terminal,
the semiconductor device is configured to be in thermal communication with the second layer of polyimide substrate, and
the second layer of polyimide substrate is bonded to the second baseplate.

4. The device of claim 1, wherein the first voltage terminal is a direct current (DC) terminal.

5. The device of claim 1, wherein the first voltage terminal is an alternating current (AC) terminal.

6. The device of claim 1, wherein the first voltage terminal is a gate terminal.

7. The device of claim 3, wherein the second voltage terminal is a DC terminal.

8. The device of claim 3, wherein the second voltage terminal is an AC terminal.

9. The device of claim 3, wherein the second voltage terminal is a gate terminal.

10. A device comprising:
a first plate being substantially planar;
a second plate being substantially planar and configured to be substantially parallel to the first plate;
a first layer of polyimide substrate bonded to the first plate;
a second layer of polyimide substrate bonded to the second plate;
a first semiconductor thermally connected to the first layer of polyimide substrate; and
a second semiconductor thermally connected to the second layer of polyimide substrate; wherein:
the first semiconductor and the second semiconductor are in electrical communication by a first voltage terminal.

11. The device of claim 10, wherein the first voltage terminal is an alternating current (CD) terminal.

12. The device of claim 10, further comprising:
a first die attach connected to a first side of the first semiconductor;
a second die attach connected to a second side of the first semiconductor;
a third die attach connected to a third side of the second semiconductor;
a fourth die attach connected to a fourth side of the second semiconductor; and
a second voltage terminal; wherein:
the second voltage terminal is in thermal communication with the polyimide substrate, and
the second voltage terminal is a direct current (DC) terminal.

13. A system comprising:
a first plurality of semiconductor devices, each substantially planar;
a first voltage terminal having a substantially planar shape in a first plane, with a plurality of planar protrusions extending radially outward from a point in the first plane, each configured to be electrically connected to a surface of a respective semiconductor device;
a second voltage terminal having a substantially planar shape in a second plane, with a plurality of planar protrusions extending radially outward from a point in the first plane, each configured to be electrically connected to a surface of a respective semiconductor device;
a first polyimide substrate having a substantially planar shape, being in thermal communication with the plurality of semiconductor devices, the first voltage terminal, and the second voltage terminal; and
a first baseplate in physical contact with the polyimide substrate.

14. The system of claim 13, wherein:
the first voltage terminal is a gate terminal, and
the second voltage terminal is a direct current (DC) terminal.

15. The system of claim 13, further comprising:
a first plurality of die attaches, each configured to be in thermal communication with a respective semiconductor device and the second voltage terminal; and
a second plurality of die attaches, each configured to be in thermal communication with a respective semiconductor device and the first voltage terminal.

16. The system of claim 15, wherein the first plurality of die attaches and the second plurality of die attaches are substantially planar and comprise a metal.

17. The system of claim 13, further comprising:
a second plurality of semiconductor devices, each substantially planar;
a third voltage terminal having a substantially planar shape in a first plane, with a plurality of planar protrusions extending radially outward from a point in the first plane, each configured to be electrically connected to a surface of a respective semiconductor device;
a fourth voltage terminal having a substantially planar shape in a second plane, with a plurality of planar protrusions extending radially outward from a point in the first plane, each configured to be electrically connected to a surface of a respective semiconductor device;
a second polyimide substrate having a substantially planar shape, being in thermal communication with the plurality of semiconductor devices, the first voltage terminal, and the second voltage terminal; and
a second baseplate in physical contact with the polyimide substrate.

18. The system of claim 17, wherein:
the third voltage terminal is a gate terminal, and
the fourth voltage terminal is a direct current (DC) terminal.

19. The system of claim 17, further comprising:
a third plurality of die attaches, each configured to be in thermal communication with a respective semiconductor device and the fourth voltage terminal; and
a fourth plurality of die attaches, each configured to be in thermal communication with a respective semiconductor device and the third voltage terminal.

20. The system of claim 19, wherein the third plurality of die attaches and the fourth plurality of die attaches are substantially planar and comprise a metal.
